(19) United States
(12) Patent Application Publication
(10) Pub. No.: US 2008/0157349 A1
(43) Pub. Date: Jul. 3, 2008

(54) IC package having improved structure

(75) Inventors: Ming-Lun(Simon) Szu, Chandler, AZ (US); David Gregory Howell, Chandler, AZ (US)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/647,789

(22) Filed: Dec. 28, 2006

(51) Int. Cl. H01L 23/36

(52) U.S. Cl. 257/713; 257/E23.101

(57) ABSTRACT

An electrical assembly (100) includes an IC package (1), a CPU connector and a heat sink (14). The IC package comprises a substrate (11), a die (12) generating heat and located on the substrate and having an upper surface (123), a lower surface and a pair of side walls (121) and end walls (122) connecting the upper surface and the lower surface, and a load distributor frame (13) surrounding side walls (121) and end walls (122) of the die and having a top surface (131), a bottom surface attached on the substrate, an inner surface (133) and an outer surface (134). The load distributor is distant to the die.

### BACKGROUND OF THE INVENTION

1. Field of the Invention

The present invention relates to an IC package, and more particularly to an IC package that has an improved structure to reduce the height of the IC package, and further to reduce the whole height of an assembly of an IC package and a CPU connector.

2. Description of the Prior Art

In the rapid development of computers many advancements have been seen in the areas of processor speed, communications, fault tolerance and size of individual component. Today∝s microprocessors, memory and other chips have become faster and smaller. However, with the increase in speed, reduction in the size of components, and increased density of circuitry found within a given chip/die, heat generation and dissipation have become a more critical factor than ever.

To facilitate the dissipation of the heat generated by a die, and IHS (Integrated Heat Spreader) may be affixed to the die and maybe used in conjunction with a heat sink. IHS is made from a kind of metal that has a good conductivity to absorb the heat from the die. In addition, a heat sink is placed on top of the IHS to facilitate the transfer of heat from the IHS to the ambient air. Referring to FIG. 1, an IC package 1′ is formed by affixing the die 12′ to a substrate 11′ and then placing to IHS 13′ to the on top of the die 12′ and a heat sink 14′ on the top of the IHS 13′. Further, the IC package 1′ utilizes the IHS 13′ to support a load from the heat sink 14′ and distribute this load to the substrate 11′. However, because the IHS 13′ will increase the height of the IC package 1′ and is not suitable for low profile products like Notebook or other handheld products.

Thus, an IC package having an improved structure which can overcome the above mentioned defects of IC package is requisite.

### SUMMARY OF THE INVENTION

Accordingly, an object of the present invention is to provide an IC package for reducing the height of the IC package.

To fulfill the above-mentioned objects, an electrical assembly accordance with a preferred embodiment comprises an IC package, a CPU connector and a heat sink.

The CPU connector comprises an insulative housing of a generally rectangular shape, a plurality of terminals received the insulative housing, a stiffener surrounding the insulative housing, and a retention structure having a load plate and a load lever respectively attached to opposite ends of the stiffener. The IC package is positioned between the load plate and the insulative housing and comprises a substrate, a die generating heat and located on the substrate and having an upper surface, a lower surface and a pair of side walls and end walls connecting the upper surface and the lower surface, and a load distributor frame surrounding side walls and end walls of the die and having a top surface, a bottom surface attached on the substrate, an inner surface and an outer surface. The load distributor is distant to the die. The heat sink is attached no the load distributor frame of the IC package.

Other objects, advantages and novel features of the present invention will become more apparent from the following detailed description when taken in conjunction with the accompanying drawings.

### BRIEF DESCRIPTION OF THE DRAWINGS

FIG. 1 is a cross section view of an IC package and a heat sink assembly of prior art;

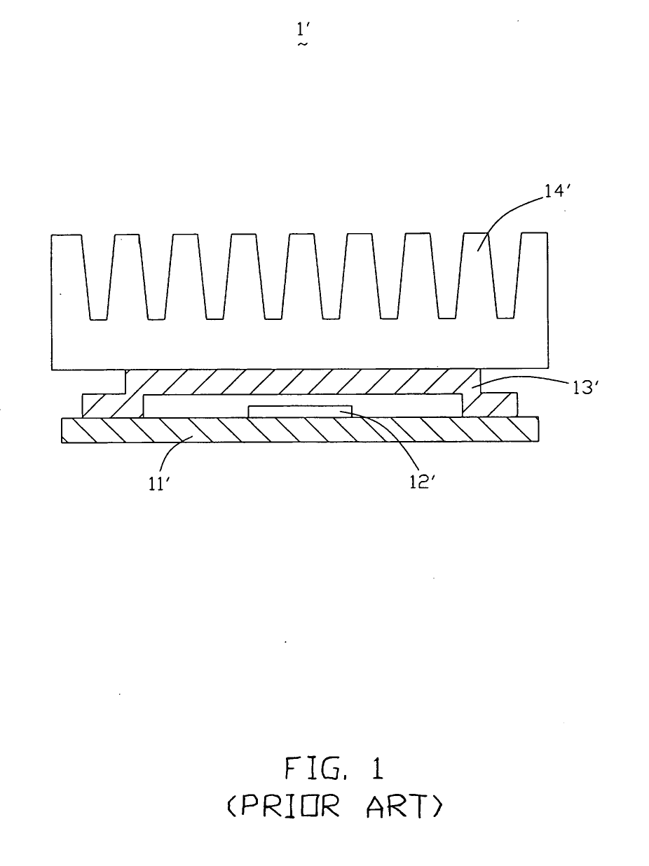

FIG. 2 is an exploded, isometric view of an assembly of the present invention which comprising a CPU connector, an IC package and a heat sink;

FIG. 3 is a cross section view of an IC package of the present invention; and

FIG. 4 is an exploded, isometric view of another assembly of the present invention which comprising another CPU connector, an IC package and a heat sink.

### DESCRIPTION OF PREFERRED EMBODIMENT OF THE INVENTION

Reference will now be made to the drawings to describe the present invention in detail.

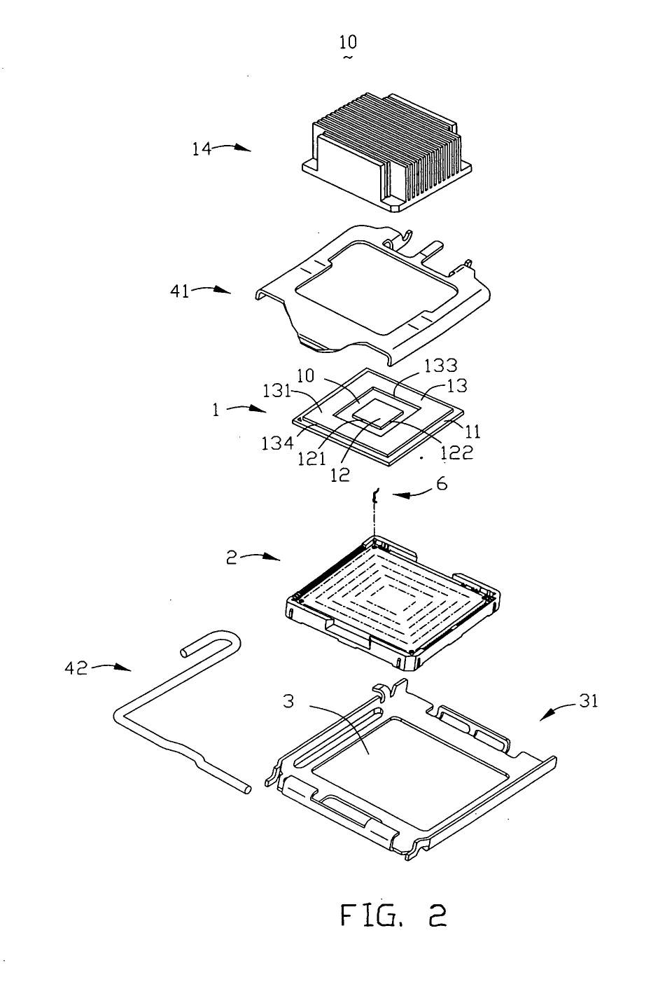

FIG. 2 depicts an embodiment of an electrical assembly 100 of an IC package 1, a CPU connector and a heat sink 14. The CPU connector comprises an insulative housing 2 of a generally rectangular shape, a plurality of terminals 6 held within the insulative housing 2, a stiffener 3 defining an opening 31 for surrounding a periphery edges of the insulative housing 2, a retention structure having a load plate 41 and a load lever 42 cooperate to forcibly press together the IC package 1 and the insulative housing 2. The heat sink 14 is attached on the IC package 1.

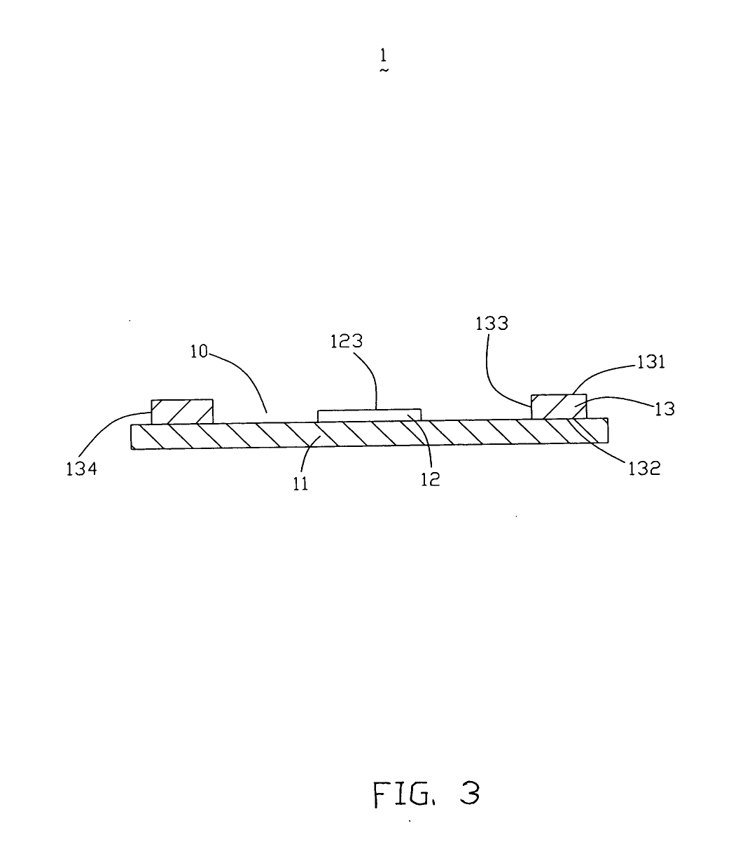

FIG. 3 depicts the package 1 comprises a substrate 11, a die 12 attached to a substrate 11 and having an upper surface 123, a lower surface (not labeled), a pair of side walls 121 and end walls 122 connecting the upper surface 123 and the lower surface, and a load distributor frame 13 shaped a rectangular figure and surrounding the side walls 121 and end walls 122 of the die 12. The load distributor frame 13 has a top surface 131, a bottom surface 132 attached on the substrate 11, an inner surface 133 and an outer surface 134. A space 10 is defined between each side wall 121/end wall 122 of the IC package 1 and the inner surface 133 of the load distributor frame 13. The upper surface 123 of the die 12 is not covered by the load distributor frame 13.

In the assembly process, the terminals 6 is pre-loaded within the insulative housing 2. The insulative housing 2 is then assembled to the stiffener 3 and the IC package 1 is located on the insulative housing 2. The stiffener 3 is interferingly coupled to the insulative housing 2, and the load plate 41 and the load lever 42 are assembled to the opposite ends of the stiffener 3. The retention structure is attached to the stiffener 3 for providing a downward force towards the IC package 1 on the insulative housing 2 so as to establish a reliable interconnection between the IC package 1 and the printed circuit board (not shown) through the CPU connector. Finally, the heat sink 14 is attached on the top surface 131 of the load distributor frame 13 for dissipating heat generated by the die 12. The load distributor frame 13 can take most of force from the load plate 41 and the heat sink 14 and disperse the force to the substrate 11. Therefore, the die 12 can avoid taking pressure from the load plate 41 and the heat sink 14 so that the die 12 cannot be damaged.

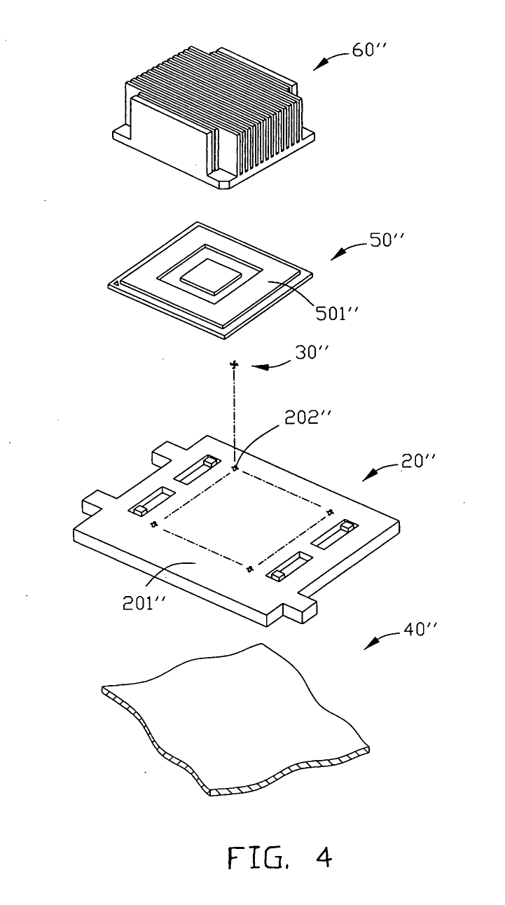

FIG. 4 depicts another embodiment of an electrical assembly of an IC package 50″, a LGA connector 20″ and a heat sink 60″. The IC package 50″ has the same structure with the IC package 1 of the first embodiment mentioned herein.

The LGA connector 20″ comprises an insulative housing 201″ defining a plurality of terminal passageways 202″, a plurality of terminals 30″ received in the passageways 202″. The LGA socket 20″ is mounted on a printed circuit board (PCB) 40″, and the IC package 50″ is movably attached to a top surface of the insulative housing 201″. The heat sink 60″ is attached on a load distributor frame 501″ of the IC package 50″ and press the IC package 50″ to connect the insulative housing 201″, thereby establishing an electrical connection between the IC package 50″ and the PCB 40″.

Although the present invention has been described with reference to a particular embodiment, it is not to be construed as being limited thereto. Various alterations and modifications can be made to the embodiment without in any way departing from the scope or spirit of the present invention the appended claims.

What is claimed is:

1. A package comprising:
a substrate;
a die mounted on an upper surface of the substrate; and
a load distributor frame mounted on the substrate and distant to the die.

2. The package as claimed in claim 1, wherein the die has an upper surface, a lower surface and a pair of side walls and end walls connecting the upper surface and the lower surface.

3. The package as claimed in claim 1, wherein the load distributor frame has a top surface, a bottom surface, an inner surface and an outer surface.

4. The package as claimed in claim 3, wherein a space is defined between each the side walls/end walls of the die and the inner surface of the load distributor.

5. An electrical assembly comprising:
a connector assembly;
an IC package mounted onto the connector, and including a load distributor with open frame in which a die is open to be accessed.

6. The electrical assembly as claimed in claim 5, further comprising a heat sink attached on the load distributor.

7. An electrical connector assembly comprising:
a printed circuit board;
an electronic package located above and electrically connected to the printed circuit board, said electronic package including:
a substrate;
a die located around a central area of an upper surface of the substrate; and
load distributor structures formed on the upper surface of the substrate and being higher than the die; wherein
the die is not covered by the lead distributor structures in a vertical direction.

8. The electrical connector assembly as claimed in claim 7, wherein a heat sink is assembled on a top of said load distributor structures in an intimate relation.

9. The electrical connector assembly as claimed in claim 7, wherein an electrical connector is located between the printed circuit board and the electronic package as an interface having a plurality of contacts thereof.

10. The electrical connector assembly as claimed in claim 7, wherein said load distributor structures essentially fully circumferentially surrounds said die instead of partially.

11. The electrical connector assembly as claimed in claim 7, wherein no portions of said distributor structures is suspended above the substrate but directly seated thereon.
